(19) United States
(12) Patent Application Publication
(10) Pub. No.: US 2023/0234791 A1
(43) Pub. Date: Jul. 27, 2023

(54) SUBSTRATE HOLDING APPARATUS

(71) Applicant: KAWASAKI JUKOGYO KABUSHIKI KAISHA, Kobe-shi, Hyogo (JP)

(72) Inventor: Shinya KINOSHITA, Kobe-shi (JP)

(73) Assignee: KAWASAKI JUKOGYO KABUSHIKI KAISHA, Kobe-shi, Hyogo (JP)

(21) Appl. No.: 18/009,494

(22) PCT Filed: May 31, 2021
(86) PCT No.: PCT/JP2021/020704

§ 371 Date: Dec. 9, 2022

(30) Foreign Application Priority Data
Jun. 9, 2020 (JP) 2020-100113

(51) Int. Cl. B65G 47/90

(52) U.S. Cl. CPC B65G 47/907

(57) ABSTRACT

A substrate holding apparatus includes a base and holders attached to the base to hold substrates. The holders is aligned in a predetermined alignment direction, and is attached to the base so as to be detachable in parallel with a reference plane as a plane crossing the alignment direction.

### FIELD

The technique disclosed herein relates to a substrate holding apparatus.

### BACKGROUND

Typically, a substrate holding apparatus that holds a substrate has been known. For example, Patent Document 1 discloses a substrate holding apparatus that holds substrates. Specifically, the substrate holding apparatus disclosed in Patent Document 1 includes holders that hold the substrates, and delivers the substrates. The holders are attached to a pitch conversion mechanism with aligned in a substrate thickness direction. In this state, the holders are attached to the pitch conversion mechanism in the order from the bottom.

### CITATION LIST

### Patent Document

Patent Document 1: Japanese Unexamined Patent Application Publication No. 2006-313865

### SUMMARY OF THE INVENTION

In some cases, in the substrate holding apparatus, the holder is detached from the substrate holding apparatus for the purpose of maintenance or replacement. However, in the above-described configuration, even in a case where only some holders are intended to be detached, it is necessary to detach the holders which are not necessarily detached or disassemble the entirety of the substrate holding apparatus.

The technique disclosed herein has been made in view of the above-described point, and an object thereof is to improve maintenance of the substrate holding apparatus.

The substrate holding apparatus disclosed herein includes a base and holders attached to the base to hold a substrate. The holders are aligned in a predetermined alignment direction, and are attached to the base so as to be detachable in parallel with a reference plane as a virtual plane crossing the alignment direction.

According to the substrate holding apparatus, maintenance of the substrate holding apparatus can be improved.

### BRIEF DESCRIPTION OF THE DRAWINGS

FIG. 1 is a schematic front view of a substrate delivery robot.

FIG. 2 is a side view of a substrate holding apparatus.

FIG. 3 is a plan view of the substrate holding apparatus.

FIG. 4 is a perspective view of the substrate holding apparatus.

FIG. 5 is a perspective view of an attachment of an odd-numbered holder.

FIG. 6 is a plan view of an even-numbered holder.

FIG. 7 is a sectional view of the attachment along a VII-VII line of FIG. 3.

FIG. 8 is a sectional view of the attachment along a VIII-VIII line of FIG. 3.

FIG. 9 is a sectional view of an inclination adjuster.

FIG. 10 is a perspective view of a base.

FIG. 11 is a perspective view of the base with some attachment blocks detached.

FIG. 12 is a schematic view showing the state of an engager when an interval between the holders is a first pitch.

FIG. 13 is a schematic view showing the state of the engager when the interval between the holders is a second pitch.

FIG. 14 is a schematic view showing part of the substrate holding apparatus in the section along the VII-VII line of FIG. 3.

FIG. 15 is a plan view of the substrate holding apparatus for describing a state in which one holder is attached or detached.

### DESCRIPTION OF EMBODIMENTS

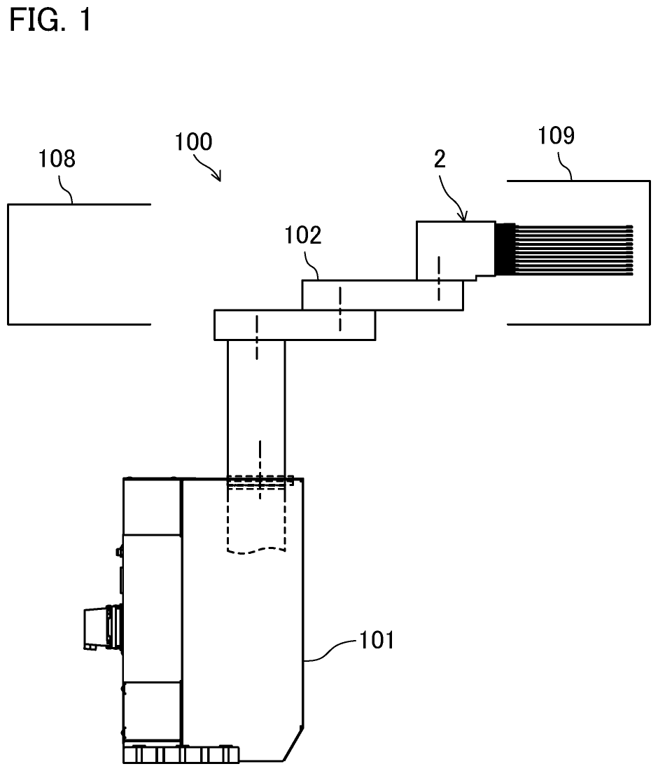

Hereinafter, an exemplary embodiment will be described in detail with reference to the drawings. FIG. 1 is a schematic front view of a substrate delivery robot 100.

The substrate delivery robot 100 includes a mount 101, a robot arm 102 coupled to the mount 101, and a substrate holding apparatus 2 coupled to the robot arm 102. The substrate delivery robot 100 is an apparatus that delivers a substrate. For example, the substrate delivery robot 100 delivers the substrate between a first housing 108 and a second housing 109. For example, the first housing is a FOUP, and the second housing is a port.

For example, the substrate is a semiconductor wafer or a glass substrate. The semiconductor wafer is, for example, a silicon wafer, a silicon carbide wafer, or a sapphire wafer. The glass substrate is, for example, a glass substrate for a flat-screen display (a liquid crystal display or an organic EL display) processed by a semiconductor process.

The robot arm 102 has joints, and deforms or moves according to the joints. For example, the robot arm 102 is a horizontal articulated arm. The substrate holding apparatus 2 is coupled to a tip end portion of the robot arm 102 so as to rotate about an axis extending in an up-down direction.

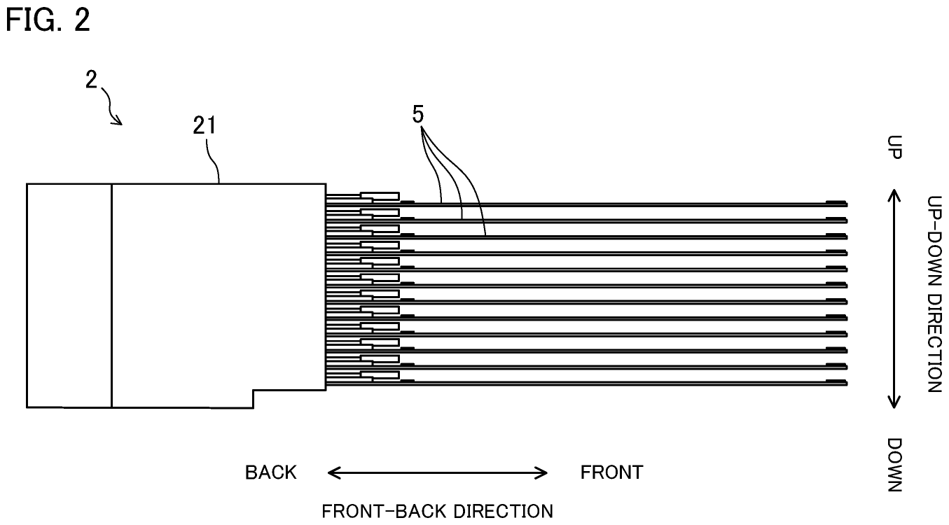

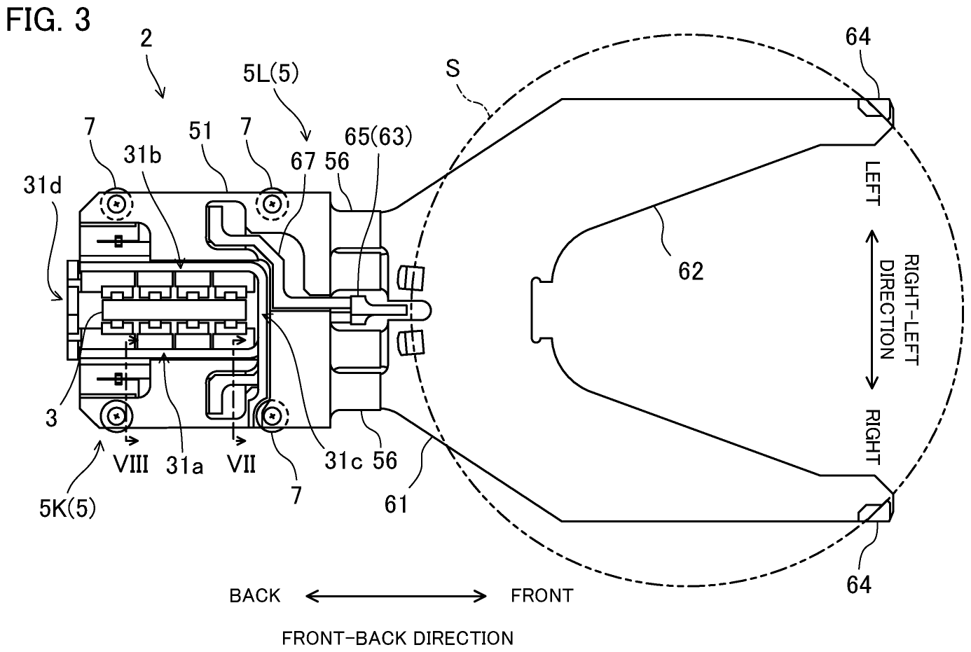

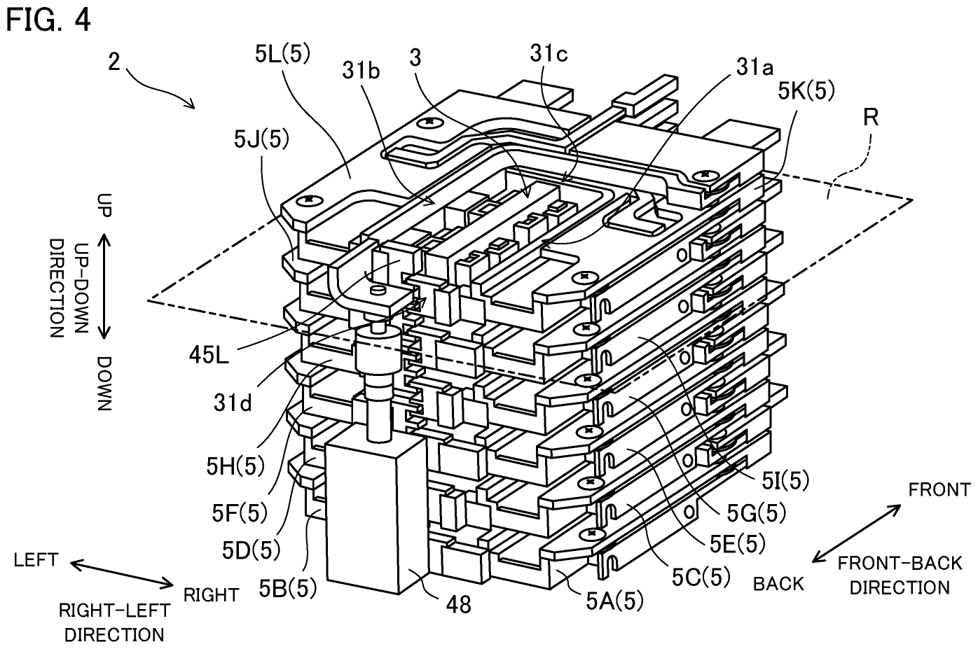

FIG. 2 is a side view of the substrate holding apparatus 2. FIG. 3 is a plan view of the substrate holding apparatus 2. FIG. 4 is a perspective view of the substrate holding apparatus 2. The substrate holding apparatus 2 includes a base 3 and holders 5 attached to the base 3 to hold substrates. In the substrate holding apparatus 2, the base 3 is covered with a casing 21. In FIGS. 3 and 4, the casing 21 is not shown. In FIG. 4, part of the holders 5 is not shown. The substrate holding apparatus 2 includes 12 holders 5 to hold 12 substrates.

The holders 5 are aligned at intervals in a predetermined alignment direction. The alignment direction is coincident with a substrate thickness direction. Hereinafter, the alignment direction will be described as the up-down direction for the sake of convenience in description. Moreover, one direction perpendicular to the up-down direction is a front-back direction, and a direction perpendicular to the up-down direction and the front-back direction is a right-left direction.

The base 3 has sides 31 facing directions perpendicular to the alignment direction. In this example, the base 3 has a first side 31a, a second side 31b, a third side 31c, and a fourth side 31d. The first side 31a and the second side 31b face the right-left direction. Specifically, the first side 31a faces the right side in the right-left direction, and the second side 31b faces the left side in the right-left direction. That is, the first side 31a and the second side 31b are located so as to face the opposite directions. The third side 31c and the fourth side 31d face the front-back direction. Specifically, the third side 31c faces the front side in the front-back direction, and the fourth side 31d faces the back side in the front-back direction. That is, the third side 31c and the fourth side 31d are located so as to face the opposite directions. The base 3 is in a substantially rectangular parallelepiped shape.

The holders 5 are attached to the first side 31a. The holders 5 are attached to the second side 31b. Specifically, the holders 5 are alternately attached to the first side 31a and the second side 31b in an order of the holders 5 being aligned in the alignment direction. For example, in the order from the bottom to the top, the odd-numbered holders 5 are attached to the first side 31a, and the even-numbered holders 5 are attached to the second side 31b. Hereinafter, in a case where the holders 5 are distinguished from each other, an uppercase alphabetic character is assigned to the end of the holder 5 in the order from the bottom. For example, the lowermost holder 5 is represented as a “holder 5A,” and the second holder 5 from the bottom is represented as a “holder 5B.” In a case where the holders 5 are not distinguished from each other, the holder 5 is merely represented as a “holder 5.”

The odd-numbered holder 5 and the even-numbered holder 5 have the same basic configuration. The odd-numbered holder 5 and the even-numbered holder 5 have shapes substantially bilaterally symmetrical to each other.

As shown in FIG. 3, the holder 5 has an attachment 51 to be attached to the base 3 and a holding portion 61 that holds the substrate. The holder 5 may further have inclination adjusters 7 that adjust inclination of the holding portion 61 with respect to the base 3. The odd-numbered holder 5 and the even-numbered holder 5 have the same functions of the attachment 51, the holding portion 61, and the inclination adjuster 7, but are different from each other in the shapes or locations thereof.

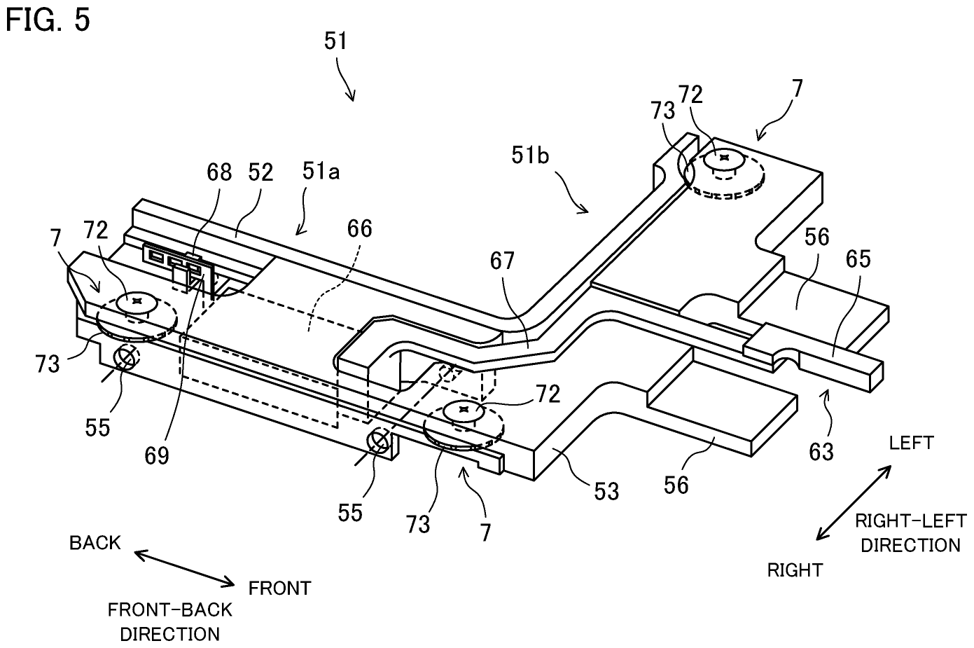

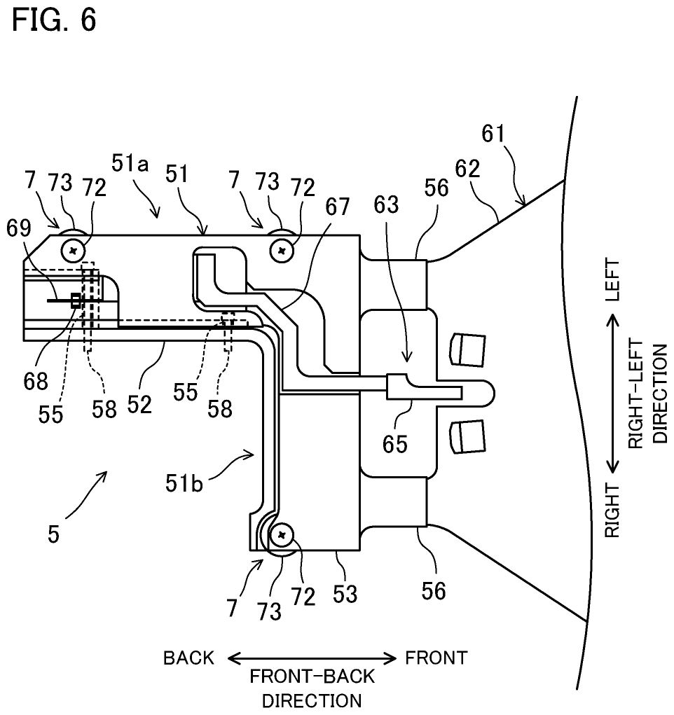

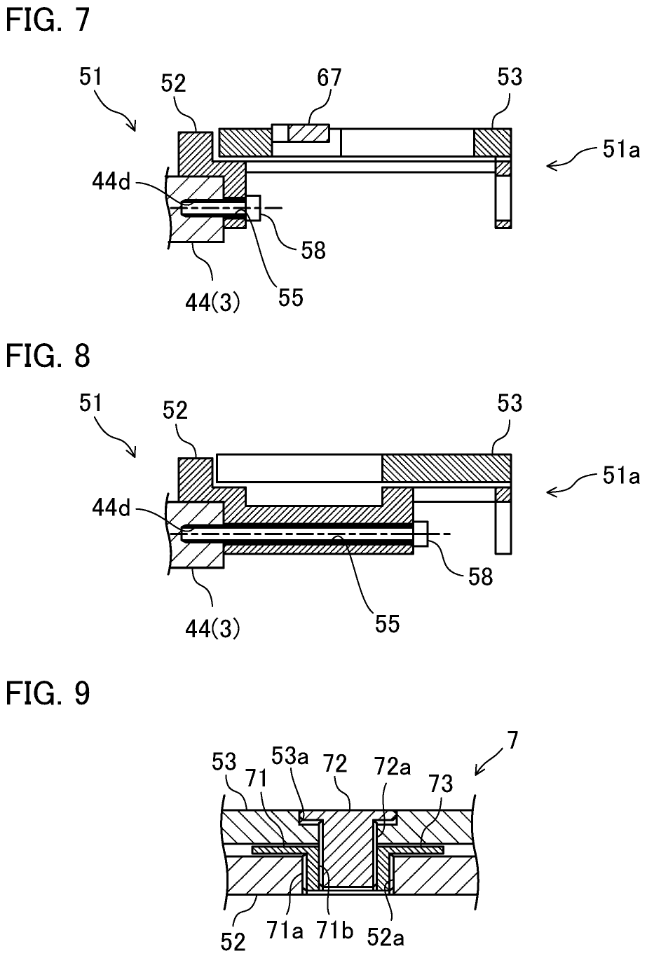

FIG. 5 is a perspective view of the attachment 51 of the odd-numbered holder 5. FIG. 6 is a plan view of the even-numbered holder 5. FIG. 7 is a sectional view of the attachment 51 along a VII-VII line of FIG. 3. FIG. 8 is a sectional view of the attachment 51 along a VIII-VIII line of FIG. 3.

The attachment 51 is in the shape of a plate extending in a plane (i.e., the horizontal plane) perpendicular to the up-down direction. The attachment 51 has a front-back portion 51a extending in the front-back direction and a right-left portion 51b extending in the right-left direction, and is in a substantially L-shaped as viewed in plane. Of the attachment 51 of the odd-numbered holder 5, the right-left portion 51b extends leftward from a front end portion of the front-back portion 51a, as shown in FIG. 5. Of the attachment 51 of the even-numbered holder 5, the right-left portion 51b extends rightward from a front end portion of the front-back portion 51a, as shown in FIG. 6. The right-left portion 51b is thinner than the front-back portion 51a.

The attachment 51 has a divided structure of a first portion 52 and a second portion 53. The first portion 52 is a portion to be attached to the base 3. The second portion 53 is a portion to which the holding portion 61 is to be attached. The second portion 53 is attached to the first portion 52 from above.

As shown in FIGS. 7 and 8, the front-back portion 51a (specifically, the front-back portion 51a at the first portion 52) has through-holes 55 into which bolts 58 are inserted when the attachment 51 is attached to the base 3. The through-hole 55 extends in the right-left direction. The through-holes 55 are located at two positions at the front-back portion 51a.

Two protrusions 56 to which the holding portion 61 is to be attached are disposed at the right-left portion 51b. An interval between two protrusions 56 in the right-left direction at the even-numbered holder 5 is wider than that at the odd-numbered holder 5.

Next, the configuration of the holding portion 61 will be described with reference to FIGS. 3 and 5.

The holding portion 61 has a body 62 in a forked shape and a holding mechanism 63. Holding by the holding portion 61 may be implemented in various forms such as gripping, suction, mounting, and fitting. In this example, the holding portion 61 grips a substrate S.

The body 62 is attached to the attachment 51. Specifically, the body 62 is attached to the protrusions 56. The body 62 extends in the forked shape in the substantially front-back direction from the attachment 51. A first claw 64 is disposed in a fixed manner at each of two tip end portions of the body 62.

The holding mechanism 63 has a movable second claw 65, an actuator 66 that drives the second claw 65, and an operation sensor 68 that detects operation of the second claw 65. The second claw 65 is located at an end portion of the body 62 to be attached to the attachment 51. The actuator 66 and the operation sensor 68 are located at the attachment 51.

The actuator 66 is, for example, an air cylinder. Compressed air is supplied to the air cylinder. The air cylinder advances and retracts a rod (not shown) by the compressed air. The second claw 65 is coupled to the actuator 66 through a coupler 67. When the rod advances, the second claw 65 moves forward in the front-back direction, i.e., moves toward the first claws 64. On the other hand, when the rod retracts, the second claw 65 moves backward in the front-back direction, i.e., moves apart from the first claws 64.

The second claw 65 advances with the substrate S positioned among the first claws 64 and the second claw 65, and accordingly, the first claws 64 and the second claw 65 engage with an edge of the substrate S. In this manner, the holding portion 61 holds the substrate S. From this state, the second claw 65 retracts, and accordingly, moves apart from the edge of the substrate S. In this manner, the holding portion 61 releases the substrate S.

The operation sensor 68 is a contact or contactless type sensor. The operation sensor 68 is, for example, an optical sensor such as a photointerrupter. The operation sensor 68 detects operation of a detection target 69 movable integrally with or in conjunction with the rod of the actuator 66 or the second claw 65, thereby detecting operation of the second claw 65.

The inclination adjuster 7 adjusts inclination of the second portion 53 with respect to the first portion 52 of the attachment 51, thereby adjusting inclination of the holding portion 61 with respect to the base 3. In this example, the holder 5 has three inclination adjusters 7. Specifically, the inclination adjusters 7 are each disposed at a back end portion of the front-back portion 51a of the attachment 51, a front end portion of the front-back portion 51a, and an end portion (a left end portion at the odd-numbered holder 5, a right end portion at the even-numbered holder 5) of the right-left portion 51b on the side opposite to the front-back portion 51a. Each inclination adjuster 7 adjusts an interval between the first portion 52 and the second portion 53 in the up-down direction. The interval between the first portion 52 and the second portion 53 in the up-down direction is adjusted at three positions at the attachment 51, and therefore, inclination (i.e., parallelism) of the second portion 53 with respect to the first portion 52 is adjusted. The first portion 52 is attached to the base 3 and the holding portion 61 is attached to the second portion 53, and as a result, inclination of the holding portion 61 with respect to the base 3 is adjusted.

For example, the inclination adjuster 7 includes a differential screw. FIG. 9 is a sectional view of the inclination adjuster 7. The inclination adjuster 7 has a first screw 71 and a second screw 72. The first screw 71 has an external thread 71a and an internal thread 71b. The pitch of the external thread 71a and the pitch of the internal thread 71b are different from each other. The external thread 71a is screwed with an internal thread 52a located at the first portion 52 and extending in the up-down direction. The second screw 72 has an external thread 72a. The second screw 72 is inserted into a through-hole 53a located at the second portion 53 and extending in the up-down direction. The external thread 72a is screwed with the internal thread 71b of the first screw 71. Rotation of the second screw 72 is stopped such that the second screw 72 does not rotate relative to the second portion 53.

The first screw 71 has a circular ring-shaped operator 73 coaxial with the external thread 71a and the internal thread 71b. As shown in FIGS. 5 and 6, part of the operator 73 projects outward from the first portion 52 and the second portion 53. For example, as viewed in plane, part of the operator 73 projects in a direction parallel with the horizontal plane from an edge of the first portion 52 and an edge of the second portion 53. Thus, a user can operate the operator 73 from the direction parallel with the horizontal plane in a state in which the holder 5 is attached to the base 3, thereby rotating the first screw 71.

When the first screw 71 rotates, the first screw 71 moves relative to the first portion 52 in the up-down direction according to the pitch of the external thread 71a. Meanwhile, the second screw 72 moves relative to the first screw 71 in the up-down direction according to the pitch of the internal thread 71b. Since the pitch of the external thread 71a and the pitch of the internal thread 71b are different from each other, the amount of relative movement of the first portion 52 and the first screw 71 and the amount of relative movement of the first screw 71 and the second screw 72 are different from each other. According to such a difference in the relative movement amount, the interval between the first portion 52 and the second portion 53 in the up-down direction changes.

Since such adjustment of the interval between the first portion 52 and the second portion 53 in the up-down direction is performed at three positions at the attachment 51, inclination of the second portion 53 with respect to the first portion 52 and therefore inclination of the holding portion 61 with respect to the base 3 are adjusted.

The attachment 51 of the holder 5 configured as described above is attached to the base 3. Specifically, the odd-numbered holder 5 is attached to the base 3 such that the front-back portion 51a of the attachment 51 is along the first side 31a of the base 3. At the first side 31a, the front-back portions 51a of the attachments 51 of the odd-numbered holders 5 are attached with aligned in the alignment direction. The even-numbered holder 5 is attached to the base 3 such that the front-back portion 51a of the attachment 51 is along the second side 31b of the base 3. At the second side 31b, the front-back portions 51a of the attachments 51 of the even-numbered holders 5 are attached with aligned in the alignment direction.

In this case, the right-left portion 51b of the attachment 51 of any of the odd-numbered and even-numbered holders 5 is located at a position facing the third side 31c of the base 3. Thus, the holding portion 61 of each holder 5 is located with aligned with the base 3 in the front-back direction. At the front of the base 3, the right-left portions 51b and the holding portions 61 of all of the holders 5 are aligned in the alignment direction, i.e., the up-down direction.

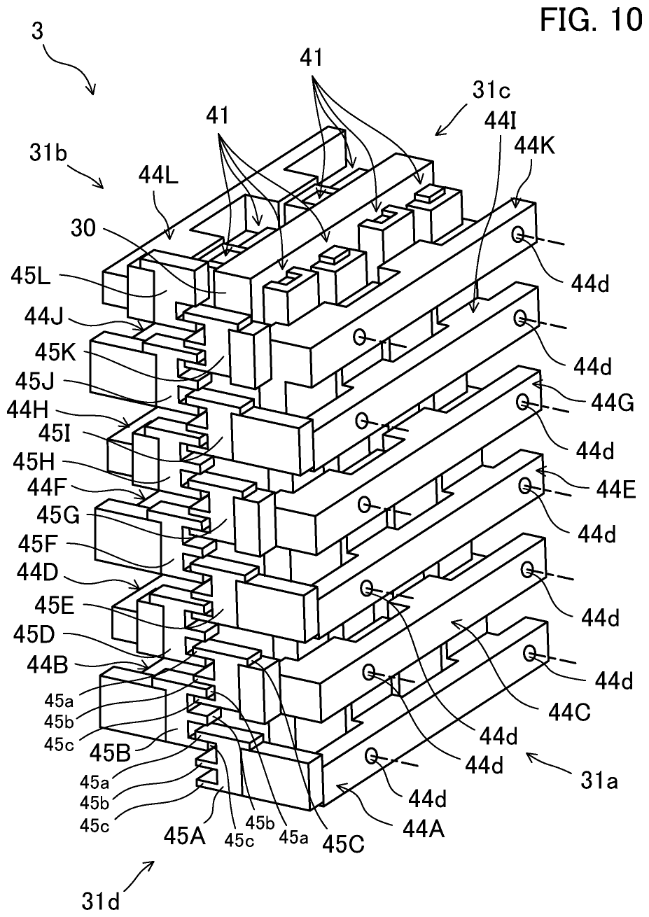

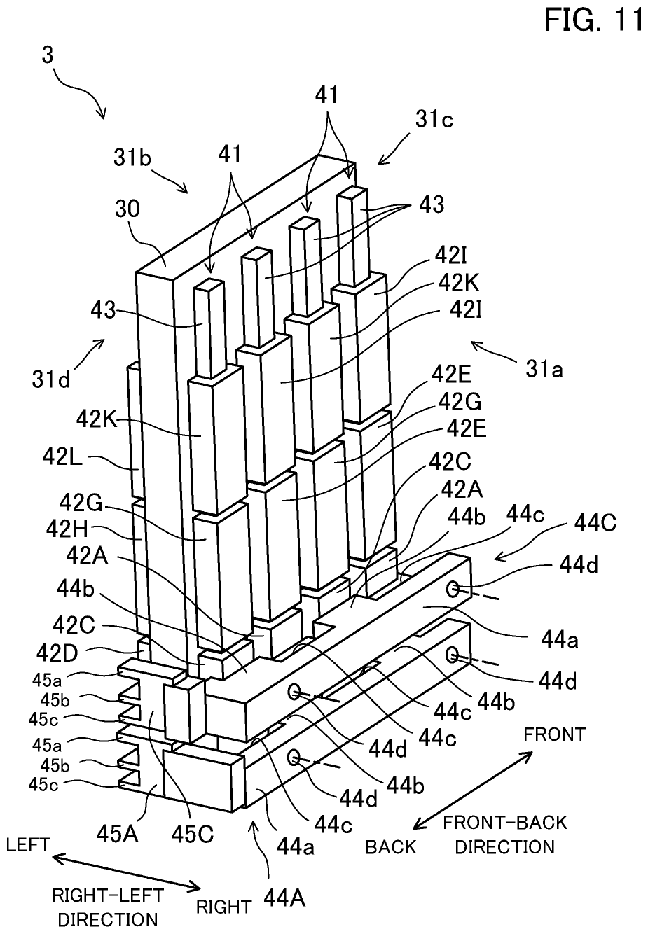

Subsequently, the configuration of the base 3 will be described in detail. FIG. 10 is a perspective view of the base 3. FIG. 11 is a perspective view of the base 3 with some attachment blocks 44 detached. Specifically, in FIG. 11, only the first attachment block 44A and the third attachment block 44C from the bottom are attached.

The base 3 has a pitch adjuster 4 that adjusts each interval between the holders 5 in the alignment direction. The pitch adjuster 4 adjusts each interval between the holders 5 to a first pitch or a second pitch greater than the first pitch. The pitch adjuster 4 has linear guides 41, the attachment blocks 44, engagers 45, and an actuator 48 (see FIG. 4).

The linear guides 41 are disposed at a body 30 of the base 3. Specifically, four linear guides 41 are disposed at the first side 31a of the base 3, and four linear guides 41 are disposed at the second side 31b of the base 3. Each linear guide 41 has slide blocks 42 and a rail 43 that guides the slide blocks 42 in the alignment direction of the holders 5, i.e., the up-down direction. Four linear guides 41 disposed at each of the first side 31a and the second side 31b are aligned at equal intervals in the front-back direction. Three slide blocks 42 are disposed on one rail 43.

For each holder 5, the corresponding slide blocks 42, the corresponding attachment block 44, and the corresponding engager 45 are assigned. Thus, the same alphabetic character as that assigned to the end of the reference numeral of the corresponding holder 5 is assigned to the ends of the reference numerals of the slide block 42, the attachment block 44, and the engager 45. These reference numerals show a correspondence relationship with the holder 5. For example, the slide block 42A, the attachment block 44A, and the engager 45A correspond to the first holder 5A. Note that in a case where these components are not distinguished from each other in terms of the correspondence relationship with the holder 5, these components will be merely referred to as a “slide block 42,” an “attachment block 44,” and an “engager 45.”

The attachment block 44 is a member for attaching the holder 5 to the slide blocks 42. The attachment block 44 is attached to the slide blocks 42, and the holder 5 is attached to the attachment block 44. That is, the holder 5 is indirectly attached to the slide blocks 42 through the attachment block 44.

Specifically, four linear guides 41, each of which has three slide blocks 42, are disposed at the first side 31a of the base 3, and therefore, 12 slide blocks 42 are disposed in total. Two slide blocks 42 at the first side 31a are assigned to each of six odd-numbered holders 5 to be attached to the first side 31a.

Similarly, four linear guides 41, each of which has three slide blocks 42, are disposed at the second side 31b of the base 3, and therefore, 12 slide blocks 42 are disposed in total. Two slide blocks 42 at the second side 31b are assigned to each of six even-numbered holders 5 to be attached to the second side 31b.

Specifically, at the first side 31a, three rows, in each of which four slide blocks 42 are aligned in the front-back direction, of the slide blocks 42 are located in the up-down direction, and therefore, 12 slide blocks 42 are located in a matrix. The foremost column in the front-back direction is a first column, and the lowermost row in the up-down direction is a first row. The slide blocks 42A, 42A assigned to the first holder 5A are located in the first and third columns in the first row. The slide blocks 42C, 42C assigned to the third holder 5C are located in the second and fourth columns in the first row. The slide blocks 42E, 42E assigned to the fifth holder 5E are located in the first and third columns in the second row. The slide blocks 42G, 42I, 42K assigned to the seventh, ninth, and eleventh holders 5G, 5I, 5K are also similarly located.

One attachment block 44 is attached to two slide blocks 42 assigned to each holder 5.

Specifically, the attachment block 44A is attached to the slide blocks 42A, 42A of four slide blocks 42 in the first row, and one attachment block 44C is attached to the slide blocks 42C, 42C of four slide blocks 42 in the first row. The attachment block 44A and the attachment block 44C are aligned in the alignment direction, and the attachment block 44C is positioned above the attachment block 44A.

The same also applies to the second and third rows. The attachment block 44E is attached to the slide blocks 42E, 42E, and the attachment block 44G is attached to the slide blocks 42G, 42G. The attachment block 44G is positioned above the attachment block 44E. The attachment block 44I is attached to the slide blocks 42I, 42I, and the attachment block 44K is attached to the slide blocks 42K, 42K. The attachment block 44K is positioned above the attachment block 44I.

The attachment block 44A and the attachment block 44C are slightly different from each other in a shape. The same also applies to the attachment blocks 44 in the second and third rows, and the attachment block 44 attached to the slide blocks 42 in the first and third columns and the attachment block 44 attached to the slide blocks 42 in the second and fourth columns are slightly different from each other in a shape. Hereinafter, in a case where these attachment blocks are distinguished from each other, the attachment block 44 attached to the slide blocks 42 in the first and third columns will be referred to as a “lower attachment block 44,” and the attachment block 44 attached to the slide blocks 42 in the second and fourth columns will be referred to as an “upper attachment block 44.” That is, the attachment blocks 44A, 44E, 44I are the lower attachment blocks 44, and the attachment blocks 44C, 44G, 44K are the upper attachment blocks.

As a configuration common between the lower attachment block 44 and the upper attachment block 44, the attachment block 44 has a body 44a extending in the front-back direction and two attachments 44b to be attached to two slide blocks 42.

Two attachments 44b of the lower attachment block 44 are located at positions corresponding to the slide blocks 42 in the first and third columns, and extend upward from the body 44a. The body 44a of the upper attachment block 44 has two cutouts 44c for avoiding interference with two attachments 44b of the lower attachment block 44.

On the other hand, two attachments 44b of the upper attachment block 44 are located at positions corresponding to the slide blocks 42 in the second and fourth columns, and extend downward from the body 44a. The body 44a of the lower attachment block 44 has two cutouts 44c for avoiding interference with two attachments 44b of the upper attachment block 44.

As another configuration common between the lower attachment block 44 and the upper attachment block 44, the body 44a has screw holes 44d for attaching the holder 5. The body 44a has two screw holes 44d aligned in the front-back direction. The screw hole 44d extends in parallel with a reference plane R (see FIG. 4) as a virtual plane crossing the alignment direction, i.e., extends in the right-left direction.

The same also applies to the second side 31b. Although not shown in the figure, three rows, in each of which four slide blocks are aligned in the front-back direction, of the slide blocks are located in the up-down direction and 12 slide blocks are located in a matrix at the second side 31b. The second holder 5B is assigned to the slide blocks in the first and third columns in the first row, and the attachment block 44B is attached to these slide blocks. The fourth holder 5D is assigned to the slide blocks in the second and fourth columns in the first row, and the attachment block 44D is attached to these slide blocks. The same also applies hereinafter. The sixth holder 5F and the eighth holder 5H are assigned to four slide blocks in the second row, and the attachment blocks 44F, 44H are attached to these slide blocks. The tenth holder 5J and the twelfth holder 5L are assigned to four slide blocks in the third row, and the attachment blocks 44J, 44L are attached to these slide blocks. The attachment blocks 44B, 44F, 44J are the lower attachment blocks 44, and the attachment blocks 44D, 44H, 44L are the upper attachment blocks.

The engager 45 is disposed at the attachment block 44 configured as described above. Specifically, the engager 45 is disposed at a rear end portion of the attachment block 44. That is, the engager 45 is located at the fourth side 31d of the base 3. The engagers 45 are aligned in the alignment direction. In this state, the engagers 45 are aligned in the alignment direction in the same order as that of the corresponding holders 5.

The engager 45 has a first engagement piece 45a, a second engagement piece 45b, and a third engagement piece 45c extending in a cantilever shape in the right-left direction. The first engagement piece 45a, the second engagement piece 45b, and the third engagement piece 45c are aligned in this order from the top in the up-down direction.

At the engager 45 of the attachment block 44 located at the first side 31a, the first engagement piece 45a, the second engagement piece 45b, and the third engagement piece 45c extend leftward. That is, a clearance between the first engagement piece 45a and the second engagement piece 45b and a clearance between the second engagement piece 45b and the third engagement piece 45c open to the left side. On the other hand, at the engager 45 of the attachment block 44 located at the second side 31b, the first engagement piece 45a, the second engagement piece 45b, and the third engagement piece 45c extend rightward. That is, a clearance between the first engagement piece 45a and the second engagement piece 45b and a clearance between the second engagement piece 45b and the third engagement piece 45c open to the right side.

Note that the twelfth engager 45L does not have the first engagement piece 45a, but has the second engagement piece 45b and the third engagement piece 45c.

Each engager 45 engages with another engager 45 adjacent thereto in the alignment direction, i.e., the up-down direction. Specifically, the first engagement piece 45a of the first engager 45A enters the clearance between the second engagement piece 45b and the third engagement piece 45c of the second engager 45B.

The third engagement piece 45c of the second engager 45B enters the clearance between the first engagement piece 45a and the second engagement piece 45b of the first engager 45A. The first engagement piece 45a of the second engager 45B enters the clearance between the second engagement piece 45b and the third engagement piece 45c of the third engager 45C.

The third engagement piece 45c of the third engager 45C enters the clearance between the first engagement piece 45a and the second engagement piece 45b of the second engager 45B. The first engagement piece 45a of the third engager 45C enters the clearance between the second engagement piece 45b and the third engagement piece 45c of the fourth engager 45D.

As described above, the first engagement piece 45a of each engager 45 enters the clearance between the second engagement piece 45b and the third engagement piece 45c of another engager 45 adjacent to such an engager 45 on the upper side thereof. The third engagement piece 45c of each engager 45 enters the clearance between the first engagement piece 45a and the second engagement piece 45b of another engager 45 adjacent to such an engager 45 on the lower side thereof.

Note that there is no engager 45 adjacent to the first engager 45A on the lower side thereof, and therefore, the first engager 45A engages only with the second engager 45B adjacent to the first engager 45A on the upper side thereof. Moreover, there is no engager 45 adjacent to the twelfth engager 45L on the upper side thereof, and therefore, the twelfth engager 45L engages only with the eleventh engager 45K adjacent to the twelfth engager 45L on the lower side thereof.

As shown in FIG. 4, the actuator 48 is coupled to the twelfth engager 45L. The actuator 48 drives the twelfth engager 45L in the alignment direction, i.e., the up-down direction. The actuator 48 is, for example, an air cylinder. The air cylinder moves, by supplied compressed air, the twelfth engager 45 upwardly or downwardly in an alternative manner.

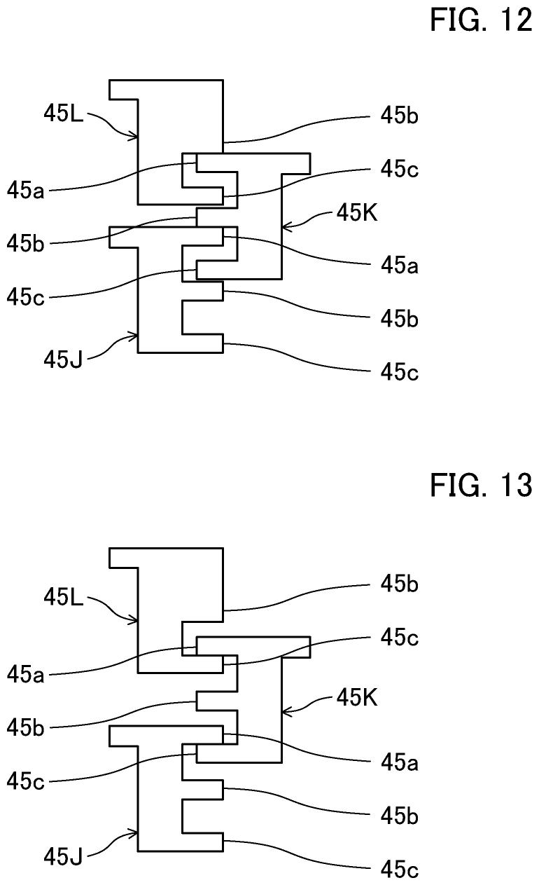

FIG. 12 is a schematic view showing the state of the engagers 45 when the interval between the holders 5 is the first pitch. FIG. 13 is a schematic view showing the state of the engagers 45 when the interval between the holders 5 is the second pitch. Note that FIGS. 12 and 13 show the tenth, eleventh, and twelfth engagers 45J, 45K, 45L.

When the twelfth engager 45L is located at the lowermost position by the actuator 48, the second engagement piece 45b of the twelfth engager 45L contacts the first engagement piece 45a of the eleventh engager 45K from above, and presses the eleventh engager 45K downward. Accordingly, the second engagement piece 45b of the eleventh engager 45K contacts the first engagement piece 45a of the tenth engager 45J from above, and presses the tenth engager 45J downward. Of two engagers 45 adjacent to each other in the up-down direction, the second engagement piece 45b of the upper engager 45 contacts the first engagement piece 45a of the lower engager 45, as described above. Accordingly, each interval between the holders 5 is adjusted to the first pitch.

On the other hand, when the twelfth engager 45L moves upward by the actuator 48, the third engagement piece 45c of the twelfth engager 45L contacts the first engagement piece 45a of the eleventh engager 45K from below, and lifts the eleventh engager 45K. Accordingly, the third engagement piece 45c of the eleventh engager 45K contacts the first engagement piece 45a of the tenth engager 45J from below, and lifts the tenth engager 45J. Of two engagers 45 adjacent to each other in the up-down direction, the third engagement piece 45c of the upper engager 45 contacts the first engagement piece 45a of the lower engager 45, as described above. Accordingly, each interval between the holders 5 is adjusted to the second pitch.

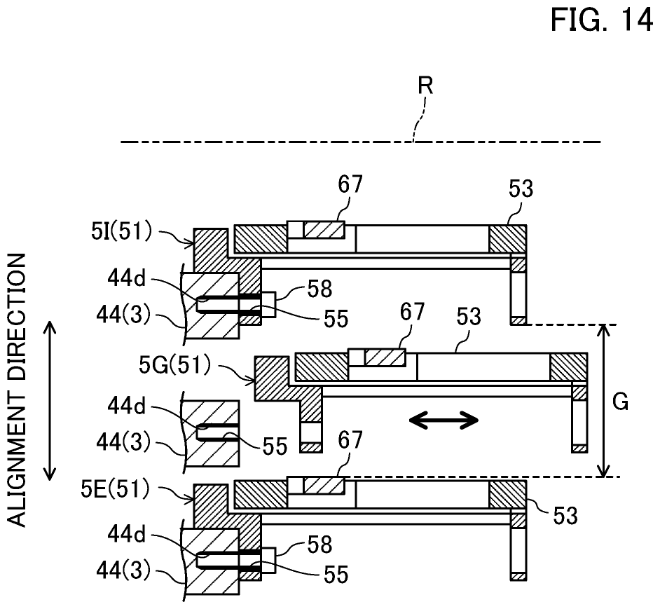

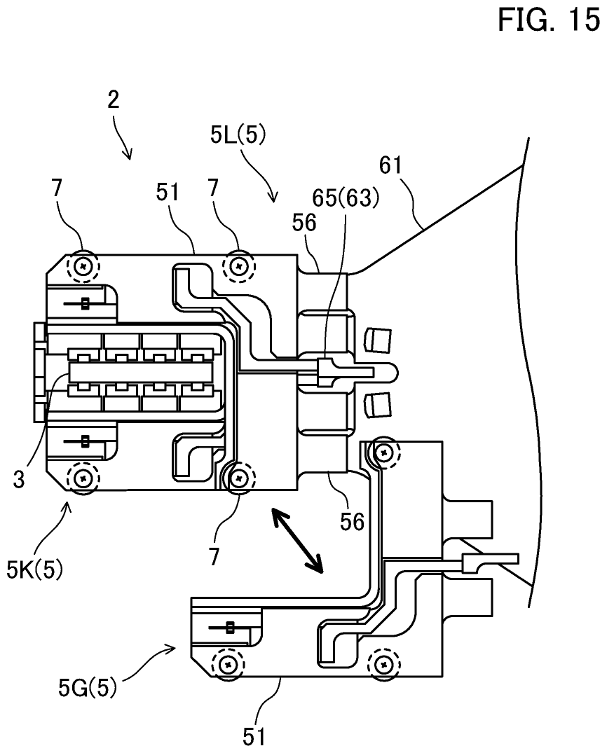

Subsequently, attachment/detachment of the holder 5 in the substrate holding apparatus 2 configured as described above will be described. FIG. 14 is a schematic view showing part of the substrate holding apparatus 2 in the section along the VII-VII line of FIG. 3. FIG. 15 is a plan view of the substrate holding apparatus 2 for describing a state in which one holder 5 is attached or detached. FIGS. 14 and 15 show a state in which the holder 5G is attached or detached.

Each holder 5 is attached to the base 3 so as to be detachable in parallel with the reference plane R as the virtual plane crossing the alignment direction. In this example, the reference plane R is the plane perpendicular to the alignment direction, i.e., the horizontal plane. Specifically, as shown in FIGS. 7 and 8, the holder 5 is attached to the attachment block 44 disposed at the base 3. The holder 5 is attached to the attachment block 44 in the horizontal direction. The holder 5 is fixed to the attachment block 44 (i.e., the base 3) with the bolts 58.

When one holder 5 is detached from the base 3 with the holders 5 attached to the base 3, the bolts 58 fixing one holder 5 to the base 3 are detached, and thereafter, one holder 5 is moved in the horizontal direction, as shown in FIG. 14. In this manner, one holder 5 can be detached from the base 3. When one holder 5 is attached to the base 3 with the holders 5 attached to the base 3, one holder 5 is moved toward the attachment block 44 in the horizontal direction to contact the attachment block 44, and thereafter, the bolts 58 are attached. In this manner, one holder 5 can be attached to the base 3.

Specifically, the odd-numbered holders 5 are aligned in the alignment direction and attached to the first side 31a of the base 3. For example, a clearance G in the alignment direction between two odd-numbered (e.g., fifth and ninth) holders 5E, 5I positioned on both sides of one odd-numbered (e.g., seventh) holder 5G in the alignment direction is greater than the dimension of one odd-numbered holder 5G in the alignment direction. Thus, when one odd-numbered holder 5G is detached from the base 3, one odd-numbered holder 5G can be moved in parallel with the reference plane R perpendicular to the alignment direction without interfering with two odd-numbered holders 5E, 5I aligned on both sides of the holder 5G in the alignment direction. Similarly, when one odd-numbered holder 5G is attached to the base 3, one odd-numbered holder 5G can be moved in parallel with the reference plane R without interfering with two odd-numbered holders 5E, 5I aligned on both sides of the holder 5G in the alignment direction. In this case, the direction of movement of one odd-numbered holder 5G may only be required to be the direction parallel with the reference plane R as shown in FIG. 15, and is not limited to the right-left direction.

The same also applies to the even-numbered holder 5 attached to the second side 31b of the base 3.

Note that this relationship is satisfied when each interval between the holders 5 is at least the second pitch, and preferably, is also satisfied when each interval between the holders 5 is at least the first pitch.

The screw hole 44d extends in parallel with the reference plane R, the screw hole 44d being located at the base 3 (specifically, the attachment block 44) such that the bolt 58 is screwed therein. Specifically, the base 3 has the pitch adjuster 4. The holder 5 is fixed to the attachment block 44 of the pitch adjuster 4 with the bolts 58. The screw holes 44d into which the bolts 58 for attaching the holder 5 are to be screwed are located at the attachment block 44. The screw hole 44d extends in parallel with the reference plane R, more specifically in the right-left direction. In a state in which the holder 5 is attached to the attachment block 44, the bolts 58 are accessible and operable from the direction parallel with the reference plane R. Specifically, at the side 31 of the base 3, the clearance G in which one holder 5 is movable in parallel with the reference plane R is located between two holders 5 positioned on both sides of one holder 5 in the alignment direction. For example, a tool is inserted into the clearance G so that the bolts 58 can be accessed and operated from the direction parallel with the reference plane R. The screw hole 44d extends in the direction parallel with the reference plane R, and therefore, a process of fastening or unfastening the bolt 58 with the tool inserted from the direction parallel with the reference plane R can be performed. As a result, the process of fastening or unfastening the bolt 58 can be performed without influence of two holders 5 positioned on both sides in the alignment direction.

As described above, the bolt 58 for fixing the holder 5 to the base 3 can be operated from the direction parallel with the reference plane R, and the holder 5 can be detached from or attached to the base 3 by movement in the direction parallel with the reference plane R. Thus, only one holder 5 can be attached to or detached from the base 3 with the other holders 5 remaining attached to the base 3.

The holding portion 61 is aligned with the base 3 in the front-back direction as a first direction of directions perpendicular to the alignment direction, and the attachments 51 of the holders 5 are attached to the first side 31a and the second side 31b, which face directions other than the front-back direction, of the sides 31. Thus, operation of the bolt 58 and an operation of attaching or detaching the holder 5 can be performed without the influence of the holding portion 61. That is, the holding portion 61 is located so as to face the third side 31c of the base 3. If the holder 5 is attached to the third side 31c, the holding portion 61 becomes an obstacle in operation of the bolt 58 or the operation of attaching or detaching the holder 5. Since the holding portion 61 is located not to face the first side 31a and the second side 31b of the base 3, operation of the bolt 58 and the operation of attaching or detaching the holder 5 can be performed without the influence of the holding portion 61.

As described above, the substrate holding apparatus 2 includes the base 3 and the holders 5 attached to the base 3 to hold the substrates. The holders 5 is aligned in the predetermined alignment direction, and is attached to the base 3 so as to be detachable in parallel with the reference plane R as the virtual plane crossing the alignment direction.

According to this configuration, the holders 5 are attachable to or detachable from the base 3 in parallel with the reference plane R crossing the alignment direction. Thus, in a state in which the holders 5 is attached to the base 3, one holder 5 can be moved in parallel with the reference plane R and be detached from the base 3 with the other holders 5 remaining attached to the base 3. For attaching one holder 5 to the base 3, one holder 5 can be moved in parallel with the reference plane R and be attached to the base 3 with the other holders 5 remaining attached to the base 3. That is, upon attachment/detachment of one holder 5, it is not necessary to disassemble the entirety of the substrate holding apparatus 2, and a state in which the other holders 5 are attached to the base 3 can be maintained. Thus, maintenance of the substrate holding apparatus 2 can be improved.

The holder 5 has the attachment 51 to be attached to the base 3 and the holding portion 61 that holds the substrate. The base 3 has the sides 31 facing the directions perpendicular to the alignment direction. The holding portion 61 is located with aligned with the base 3 in the first direction of the directions perpendicular to the alignment direction. The attachment 51 is attached to the first side 31a, which faces the direction other than the first direction, of the sides 31.

According to this configuration, the base 3 and the holding portion 61 are aligned in the first direction. Thus, if the attachment 51 is attached to the side 31, which faces the first direction, of the sides 31, the base 3, the attachment 51, and the holding portion 61 are aligned in this order in the first direction. In this case, the holding portion 61 becomes an obstacle when the attachment 51 is handled so as to be attached to or detached from the base 3. For example, in the case of fastening the attachment 51 to the base 3 in the first direction with a bolt, the holding portion 61 becomes an obstacle, and operation of the bolt 58 is complicated. Also, in the case of attaching the attachment 51 to the base 3 in the first direction, a portion of the base 3 to which the attachment 51 is attached is difficult to be visually recognized due to the presence of the holding portions 61 of the other holders 5, and a process of attaching the attachment 51 is complicated.

On the other hand, the attachment 51 is attached to the first side 31a, which faces the direction other than the first direction, of the sides 31, and therefore, the attachment 51 can be attached to or detached from the base 3 without the influence of the holding portion 61.

The sides 31 include the second side 31b facing the direction other than the first direction, and the holders 5 are alternately attached to the first side 31a and the second side 31b in the order of the holders 5 being aligned in the alignment direction.

According to this configuration, as compared to the case of attaching all of the holders 5 to one side 31, each of the first side 31a and the second side 31b has an extra space to attach the holders 5. As a result, workability in attachment of the holders 5 to the base 3 or detachment of the holders 5 from the base 3 can be improved.

The first side 31a and the second side 31b face the opposite directions.

According to this configuration, since the first side 31a and the second side 31b face the opposite directions, attachment of the holders 5 to the first side 31a or detachment of the holders 5 from the first side 31a and attachment of the holders 5 to the second side 31b or detachment of the holders 5 from the second side 31b can be performed for the base 3 from the opposite sides. Thus, influence of the holders 5 attached to the first side 31a and the holders 5 attached to the second side 31b on attachment/detachment of each holder 5 can be reduced.

Specifically, the first side 31a and the second side 31b face the directions perpendicular to the first direction.

According to this configuration, the holding portion 61, the holder 5 attached to the first side 31a, and the holder 5 attached to the second side 31b can be located with less influence on attachment/detachment of the holder 5.

The holders 5 are fixed to the base 3 with the bolts 58, and the screw holes 44d located at the base 3 such that the bolts 58 are screwed therein extend in parallel with the reference plane R.

According to this configuration, the operation of fastening or unfastening the bolt 58 for fixing the holder 5 to the base 3 is also performed in the direction parallel with the reference plane R, as in attachment/detachment of the holder 5. In a state in which the holders 5 are attached to the base 3, the space where one holder 5 is movable in parallel with the reference plane R is ensured. Thus, the operation of fastening or unfastening the bolt 58 can be performed using such a space. As a result, workability in fastening or unfastening of the bolt 58 can also be improved.

The holder 5 has the inclination adjuster 7 that adjusts inclination with respect to the base 3.

According to this configuration, inclination of the holder 5 with respect to the base 3 is adjusted by the inclination adjuster 7. Inclination of the holder 5 with respect to the base 3 also depends on the state of attachment of the holder 5 to the base 3. However, the holders 5 aligned in the alignment direction are attached to the base 3, and it is not easy to adjust inclination of the holder 5 upon attachment of the holder 5 to the base 3. With the inclination adjuster 7, inclination of the holder 5 with respect to the base 3 can be adjusted with the holders 5 attached to the base 3. In other words, it is not necessary to precisely manage inclination of the holder 5 with respect to the base 3 when the holder 5 is attached to the base 3, and therefore, workability in attachment of the holder 5 can be improved.

The inclination adjuster 7 includes the inclination adjusters 7 disposed at positions at the holder 5.

According to this configuration, inclination of the holder 5 can be adjusted at the positions at the holder 5. As a result, adjustability of inclination of the holder 5 with respect to the base 3 can be improved.

The inclination adjuster 7 is located at the position operable from the direction parallel with the reference plane R with the holder 5 attached to the base 3.

According to this configuration, operability of the inclination adjuster 7 in a state in which the holder 5 is attached to the base 3 can be improved.

The base 3 has the linear guide 41 including the slide blocks 42 and the rail 43 guiding the slide blocks 42 in the alignment direction, and the holder 5 is attached to the slide blocks 42 such that the position thereof in the alignment direction is adjustable.

According to this configuration, the holder 5 is attached to the base 3 such that the position thereof in the alignment direction is adjustable. That is, each interval between the holders 5 in the alignment direction can be adjusted. In this case, the configuration of the base 3 is complicated as compared to a configuration with no linear guide 41 etc. Even in this configuration, the holders 5 are attached to the base 3 so as to be detachable in parallel with the reference plane R so that maintenance of the holder 5 can be improved.

The attachment block 44 for attaching the holder 5 is attached to the slide blocks 42, and the holder 5 is attached to the slide blocks 42 by attachment to the attachment block 44.

According to this configuration, the holder 5 is indirectly attached to the slide blocks 42 through the attachment block 44.

<<Other Embodiments>>

The embodiment has been described above as an example of the technique disclosed in the present application. However, the technique in the present disclosure is not limited to above, and is also applicable to embodiments to which changes, replacements, additions, omissions, etc. are made as necessary. The components described above in the embodiment may be combined to form a new embodiment. The components shown in the attached drawings and described in detail may include not only components essential for solving the problems, but also components that are provided for describing an example of the above-described technique and are not essential for solving the problems. Thus, description of these non-essential components in detail and illustration of these components in the attached drawings shall not be interpreted that these non-essential components are essential.

For example, the number of holders 5 of the substrate holding apparatus 2 is not limited to 12. The number of holders 5 may only be required to be a plural number.

The interval between the holders 5 in the alignment direction may be unadjustable, i.e., fixed. That is, the pitch adjuster 4 may be omitted. In this case, the holders 5 are attached to the body 30 of the base 3.

The reference plane R may only be required to cross the alignment direction, and is not necessarily perpendicular to the alignment direction. That is, the holder 5 may be moved diagonally upward or downward with respect to the up-down direction as the alignment direction, and in this manner, may be attached to or detached from the base 3.

The holders 5 are attached to the first side 31a and the second side 31b of the base 3, but the present disclosure is not limited to above. For example, all of the holders 5 may be attached to one side 31 (e.g., the first side 31a) of the base 3.

Even in a case where the holders 5 are attached to the sides 31 of the base 3, such attachment is not limited to attachment to the first side 31a and the second side 31b, and the holders 5 may be attached to any side 31. For example, the holders 5 may be attached to the first side 31a and the fourth side 31d.

The number of inclination adjusters 7 is not limited to three. One inclination adjuster 7, two inclination adjusters 7, or four or more inclination adjusters 7 may be disposed. The holder 5 does not necessarily have the inclination adjuster 7.

The holder 5 is attached to the attachment block 44 of the pitch adjuster 4, but the present disclosure is not limited to above. For example, the pitch adjuster 4 may have no attachment blocks 44, and the holder 5 may be attached to the slide blocks 42.

### DESCRIPTION OF REFERENCE CHARACTERS

2 Substrate Holding Apparatus
3 Base
31 Side
31a First Side
31b Second Side
41 Linear Guide
42 Slide Block
43 Rail
44 Attachment Block
44d Screw Hole
5 Holder
51 Attachment
58 Bolt
61 Holding Portion
7 Inclination Adjuster
R Reference Plane

1. A substrate holding apparatus comprising:
a base; and
holders attached to the base to hold a substrate,
wherein the holders are aligned in a predetermined alignment direction, and is attached to the base so as to be detachable in parallel with a reference plane as a virtual plane crossing the alignment direction.

2. The substrate holding apparatus of claim 1, wherein
each of the holders has an attachment to be attached to the base and a holding portion that holds the substrate,
the base has sides facing directions perpendicular to the alignment direction,
the holding portion is located with aligned with the base in a first direction of the directions perpendicular to the alignment direction, and
the attachment is attached to a first side, which faces a direction other than the first direction, of the sides.

3. The substrate holding apparatus of claim 2, wherein
the sides include a second side facing a direction other than the first direction, and
the holders are alternately attached to the first side and the second side in an order of the holders being aligned in the alignment direction.

4. The substrate holding apparatus of claim 3, wherein
the first side and the second side face opposite directions.

5. The substrate holding apparatus of claim 4, wherein
the first side and the second side face directions perpendicular to the first direction.

6. The substrate holding apparatus of claim 1, wherein
the holders are fixed to the base with a bolt, and
a screw hole extends in parallel with the reference plane, the screw hole being located at the base such that the bolt is screwed therein.

7. The substrate holding apparatus of claim 1, wherein
each of the holders has an inclination adjuster that adjusts inclination with respect to the base.

8. The substrate holding apparatus of claim 7, wherein
the inclination adjuster includes inclination adjusters disposed at positions at each of the holders.

9. The substrate holding apparatus of claim 7, wherein
the inclination adjuster is located at a position operable from a direction parallel with the reference plane with each of the holders attached to the base.

10. The substrate holding apparatus of claim 1, wherein
the base has a linear guide having a slide block and a rail guiding the slide block in the alignment direction, and
each of the holders is attached to the slide block such that a position thereof in the alignment direction is adjustable.

11. The substrate holding apparatus of claim 10, wherein
an attachment block used to attach each of the holders is attached to the slide block, and
each of the holders is attached to the slide block by attaching to the attachment block.
